(19) United States
(12) Patent Application Publication
(10) Pub. No.: US 2007/0164323 A1
(43) Pub. Date: Jul. 19, 2007

(54) CMOS gates with intermetallic compound tunable work functions

(75) Inventors: Leonard Forbes, Corvallis, OR (US); Paul A. Farrar, Bluffton, SC (US); Kie Y. Ahn, Chappaqua, NY (US)

Correspondence Address: SCHWEGMAN, LUNDBERG, WOESSNER & KLUTH, P.A., P.O. BOX 2938, MINNEAPOLIS, MN, 55402, US

(73) Assignee: Micron Technology, Inc.

(21) Appl. No.: 11/333,910

(22) Filed: Jan. 18, 2006

(51) Int. Cl. H01L 29/80

(52) U.S. Cl. 257/274

(57) ABSTRACT

Gates of at least one of NMOS transistors and PMOS transistors of a CMOS integrated circuit are formed with an intermetallic compound. The work function of the gate electrode is tunable by controlling the selection of the metals that form a layer of the intermetallic compound. In one embodiment, a layer of each metal is deposited onto the gate area of a MOS transistor. At least one metal is deposited using atomic layer deposition. The intermetallic compound is formed by annealing subsequent to the deposition of the metals.

### CROSS-REFERENCE TO RELATED APPLICATIONS

This application is related to co-pending, commonly assigned U.S. patent application Ser. No. ______, entitled “CMOS GATES WITH SOLID-SOLUTION ALLOY TUNABLE WORK FUNCTIONS,” filed on ______ (Attorney Docket No. 1303.159US1); U.S. patent application Ser. No. 11/038,730, entitled “ATOMIC LAYER DEPOSITION OF CMOS GATES WITH VARIABLE WORK FUNCTIONS,” filed on Jan. 20,2005; U.S. patent application Ser. No. 10,929,822, entitled “ATOMIC LAYER DEPOSITION OF CMOS GATES WITH VARIABLE WORK FUNCTIONS,” filed on Aug. 30, 2004; U.S. patent application Ser. No. 10/754,842, entitled “ATOMIC LAYER DEPOSITION OF CMOS GATES WITH VARIABLE WORK FUNCTIONS,” filed on Jan. 9, 2004; and U.S. patent application Ser. No. 10/225,605, entitled “ATOMIC LAYER DEPOSITION OF CMOS GATES WITH VARIABLE WORK FUNCTIONS,” filed on Aug. 22, 2002; which are hereby incorporated by reference in their entirety.

### TECHNICAL FIELD

This document relates generally to semiconductor integrated circuit technology and particularly, but not by way of limitation, to complementary metal-oxide semiconductor (CMOS) transistors having gates with work functions tunable using intermetallic compounds.

### BACKGROUND

Conventional n-type doped polysilicon gate electrodes in CMOS technology have two problems. One problem is that the polysilicon is conductive but there can still be a surface region which can be depleted of carriers under bias conditions. Commonly referred to as gate depletion, this appears as an extra gate insulator thickness and contributes to the equivalent oxide thickness. While this region is thin, on the order of a few angstroms (Å), it becomes appreciable as gate oxide thicknesses are below 2 nm or 20 Å. Another problem is that the work function is not optimum for both NMOS and PMOS transistors. Historically, this was compensated for by threshold voltage adjustment implantations. However, as the devices become smaller, with channel lengths of less than 1000 Å and consequently surface space charge regions of less than 100 Å, it becomes more and more difficult to perform such implantations. Threshold voltage control becomes an important consideration as power supply voltage is reduced to about one volt. Optimum threshold voltages of both NMOS and PMOS transistors need to have a magnitude of around 0.3 volts.

The work function of the gate electrode, which is the energy needed to extract an electron, must be compatible with the barrier height of the semiconductor material. For PMOS transistors, the required work function is about 5.0 eV. Achieving the lower work function needed by NMOS transistors, which is about 4.1 eV, has been more difficult. FIGS. 1A-1C illustrate the desired energy band diagrams and work functions for NMOS and PMOS transistors. As illustrated in FIG. 1A, metals with work functions of around 4.1 eV will result in NMOS threshold voltages around zero volts on bulk CMOS devices. As illustrated in FIG. 1B, about 0.6 eV band bending will occur in the p-type silicon substrate and 0.3 eV potential drop will occur across the gate oxide. If a positive NMOS threshold voltage with a larger magnitude is required, the work function of the metal gate should be larger, such as 4.3 eV, which will give a threshold around 0.2 volts. Metals with work functions of around 5.0 eV will result in PMOS threshold voltages around zero volts on bulk CMOS devices. As illustrated in FIG. 1C, about 0.6 eV band bending will occur in the p-type silicon substrate and 0.3 eV potential drop will occur across the gate oxide. If a negative PMOS threshold voltage with a larger magnitude is required, the work function of the metal should be smaller, such as around 4.8 eV, which will result in a threshold voltage of around −0.2 volts. Mid-gap work functions around 4.6 eV will result in threshold voltages with equal magnitudes of around 0.5 eV, but these magnitudes are too large for modern nanometer-scale devices with low power supply voltages that require threshold voltages of about 0.2 to 0.3 volts.

Therefore, there is a need for improved CMOS transistor design.

### SUMMARY

Gates of at least one of NMOS transistors and PMOS transistors of a CMOS integrated circuit are formed with an intermetallic compound. The work function of the gate electrode is tunable by controlling the selection of the metals that form a layer of the intermetallic compound.

In one embodiment, a CMOS device includes NMOS and PMOS transistors. Gates of the NMOS transistors and/or the PMOS transistors each include a layer of intermetallic compound.

In one embodiment, a CMOS device includes MOS transistors each having a gate including a layer of intermetallic compound of a first metal and a second metal. A conducting layer is in contact with the layer of intermetallic compound.

In one embodiment, a method for producing a CMOS device is provided. A layer of an intermetallic compound is formed in the process of forming a gate of at least one of an NMOS transistor and a PMOS transistor.

In one embodiment, a method for producing a CMOS device is provided. A first metal and a second metal are selected for a specified threshold voltage of NMOS or PMOS transistors. The first metal and the second metal are capable of forming an intermetallic compound. A layer of the first metal is deposited to form a gate for each of the NMOS or PMOS transistors. A layer of the second metal is deposited on the layer of the first metal. Then, annealing is performed to form a layer of the intermetallic compound with the layer of the first metal and the layer of the second metal.

This Summary is an overview of some of the teachings of the present application and is not intended to be an exclusive or exhaustive treatment of the present subject matter. Further details about the present subject matter are found in the detailed description and appended claims. Other aspects of the invention will be apparent to persons skilled in the art upon reading and understanding the following detailed description and viewing the drawings that form a part thereof. The scope of the present invention is defined by the appended claims and their legal equivalents.

### BRIEF DESCRIPTION OF THE DRAWINGS

The drawings illustrate generally, by way of example, but not by way of limitation, various embodiments discussed in the present document.

FIGS. 1A-1C are illustrations of desired energy bands and work functions for CMOS transistors.

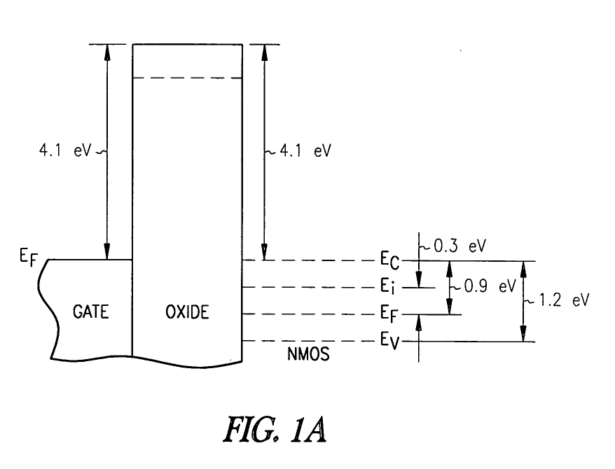

FIG. 2 is an illustration of an embodiment of a structure of portions of a CMOS device showing an NMOS transistor and a PMOS transistor.

FIGS. 3A-3C are each an illustration of an embodiment of gates of the NMOS transistor and the PMOS transistor after metal deposition and before annealing.

FIGS. 4A-4C are each an illustration of an embodiment of gates of the NMOS transistor and the PMOS transistor after the annealing.

FIG. 5 is a block diagram illustrating an embodiment of a memory device utilizing the CMOS device of FIG. 2.

FIG. 6 is a block diagram illustrating an embodiment of a processor-based system utilizing the CMOS device of FIG. 2.

### DETAILED DESCRIPTION

In the following detailed description, reference is made to the accompanying drawings which form a part hereof, and in which are shown by way of illustration specific embodiments in which the invention may be practiced. These embodiments are described in sufficient detail to enable those skilled in the art to practice the invention, and it is to be understood that the embodiments may be combined, or that other embodiments may be utilized and that structural, logical and electrical changes may be made without departing from the spirit and scope of the present invention. References to “an”, “one”, or “various” embodiments in this disclosure are not necessarily to the same embodiment, and such references contemplate more than one embodiment. The following detailed description provides examples, and the scope of the present invention is defined by the appended claims and their legal equivalents.

In this document, a “MOS transistor” refers to a metal-oxide semiconductor field-effect transistor (or MOSFET), an “NMOS transistor” refers to an n-channel metal-oxide semiconductor field-effect transistor (or n-channel MOSFET), and a “PMOS” refers to a p-channel metal-oxide semiconductor field-effect transistor (or p-channel MOSFET). An “NMOS gate” refers to the gate of an NMOS transistor. A “PMOS gate” refers to the gate of a PMOS transistor.

This document discusses, among other things, CMOS transistors having gates including an intermetallic compound layer. The choice of the metals determines the work function of the gate electrode. The intermetallic compound is formed by deposition of metal layers and subsequently annealing (heat treatment). Many intermetallic compounds exist over a range of compositions and therefore allow for achieving a range of possible work functions. As it is most desirable to have a single-phase structure in contact with the gate, these compounds are therefore easier to deposit in a controlled manner. In various embodiments, at least one metal layer is formed by atomic layer deposition (ALD). In one embodiment, a CMOS device includes one type of transistors each having a gate formed with a single metal and another type of transistors each having a gate formed with an intermetallic compound. For example, titanium (Ti) may be used as the electrode for the NMOS device, and the compound Ti₃Pt for the PMOS device. As the compound Ti₃Pt exists over the composition range of approximately 71 to 78% titanium the composition may be adjusted over this range to give a better match to the optimum threshold voltage desired. In this case, a composition at the lower titanium composition would be most desirable. In another embodiment, a CMOS device includes one type of transistors each having a gate formed with a first type intermetallic compound and another type of transistors each having a gate formed with a second type intermetallic compound. For example, the compound Pt₃Zr₅ may be used for the NMOS device, and the compound Pt₃Zr for the PMOS device. In various specific embodiments, the intermetallic compound used to form the gates of one or more types of transistors in a CMOS device include, but are not limited to, intermetallic compound of platinum (Pt) and titanium (Ti), intermetallic compound of palladium (Pd) and titanium (Ti), intermetallic compound of zirconium (Zr) and platinum (Pt), and intermetallic compound of iridium (Ir) and tantalum (Ta).

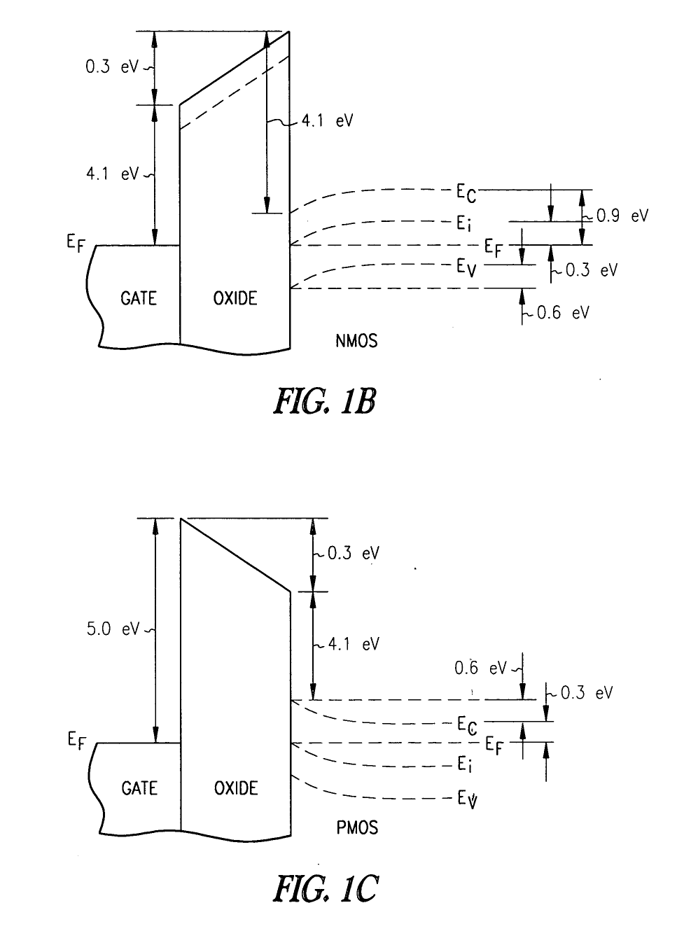

FIG. 2 is an illustration of an embodiment of a structure of portions of a CMOS device 200 including at least an NMOS transistor 201 and a PMOS transistor 221. NMOS transistor 201 and PMOS transistor 221 each have a gate formed by one or more metals.

NMOS transistor 201 has a structure including a source region 202, a drain region 204, and a channel 206 between source region 202 and drain region 204. A gate 210 is separated from channel 206 by a gate insulator 208. PMOS transistor 221 has a structure including a source region 222, a drain region 224, and a channel 226 between source region 222 and drain region 224. A gate 230 is separated from channel 226 by a gate insulator 228. In various embodiments, at least one of gate 210 and gate 230 is formed by an intermetallic compound. The metals are deposited layer by layer, and the intermetallic compound is formed by annealing subsequent to the deposition of the metals. In various embodiments, at least one layer of metal is deposited using ALD. A masking level is required to produce the areas of different composition in the gate material. For example, as the thickness of the material in contact with the gate may be only a few hundred angstroms, and it is only necessary to protect one set of gates from one of the depositions, a liftoff process could be used to remove the metal deposited in the second deposition from one set of gates.

In some embodiments, as illustrated in FIG. 2, a conducting layer 212 is deposited on gate 210, and a conducting layer 232 is deposited on gate 230. Conducting layers 212 and 232 are each made of highly conductive materials such as highly conductive polysilicon or metal. In one embodiment, the metal that forms conducting layer 212 is a constituent of the intermetallic compound of gate 210, and/or the metal that forms conducting layer 232 is a constituent of the intermetallic compound of gate 230. Examples of such constituent metals include platinum, titanium, palladium, iridium, tantalum, and zirconium. In another embodiment, the metal that forms conducting layer 212 is not a constituent of the intermetallic compound of gate 210, and/or the metal that forms conducting layer 232 is not a constituent of the intermetallic compound of gate 230. Examples of such metals include aluminum (Al), aluminum alloy, copper (Cu), copper alloy, silver (Ag), silver alloy, gold (Au), and gold alloy. The intermetallic compound may serve as part or all of a local interconnect layer (the so-called M0 layer).

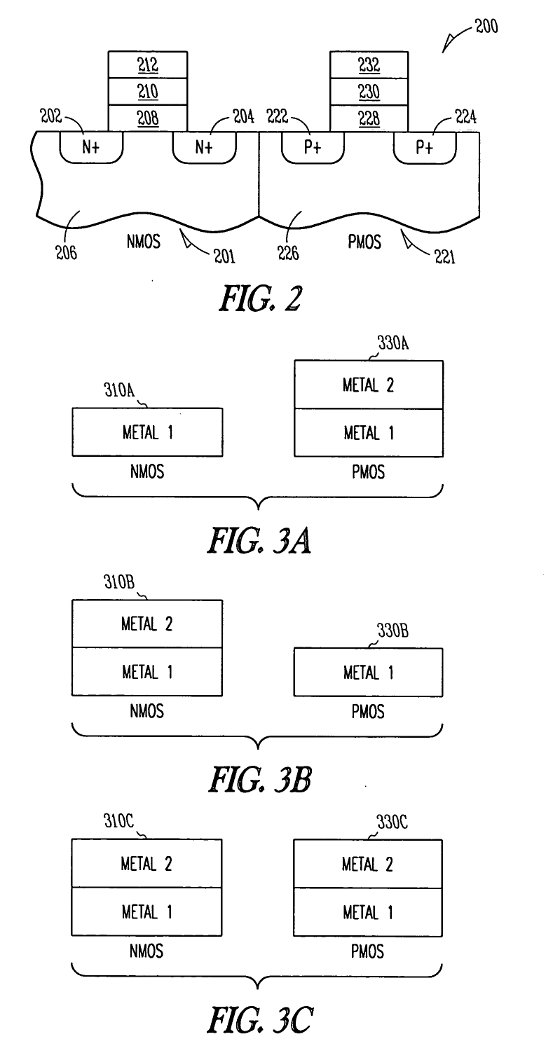

FIGS. 3A-3C are each an illustration of an embodiment of gates of NMOS and PMOS transistors after the metal deposition and before the formation of the intermetallic compound. The gates are formed with at least two metals, labeled as Metal 1 and Metal 2. In various embodiments, at least one of Metal 1 and Metal 2 is deposited by ALD. In one embodiment, Metal 1 is titanium, and Metal 2 is platinum. In another embodiment, Metal 1 is titanium, and Metal 2 is palladium. In another embodiment, Metal 1 is tantalum, and Metal 2 is iridium.

FIG. 3A illustrates an NMOS gate 310A and a PMOS gate 330A. NMOS gate 310A illustrates a specific embodiment of gate 210 of NMOS transistor 201. PMOS gate 330A illustrates a specific embodiment of gate 230 of PMOS transistor 221. To form NMOS gate 310A, only Metal 1 is deposited. To form PMOS gate 330A, Metal 1 is deposited first, and Metal 2 is deposited on Metal 1.

FIG. 3B illustrates an NMOS gate 310B and a PMOS gate 330B. NMOS gate 310B illustrates another specific embodiment of gate 210 of NMOS transistor 201. PMOS gate 330B illustrates another specific embodiment of gate 230 of PMOS transistor 221. To form NMOS gate 310B, Metal 1 is deposited first, and Metal 2 is deposited on Metal 1. To form PMOS gate 330B, only Metal 1 is deposited.

FIG. 3C illustrates an NMOS gate 310C and a PMOS gate 330C. NMOS gate 310C illustrates another specific embodiment of gate 210 of NMOS transistor 201. PMOS gate 330C illustrates another specific embodiment of gate 230 of PMOS transistor 221. To form NMOS gate 310C, Metal 1 is deposited first, and Metal 2 is deposited on Metal 1. To form PMOS gate 330C, Metal 1 is deposited first, and Metal 2 is deposited on Metal 1. In another specific embodiment, the combination of Metal 1 and Metal 2 for NMOS gate 310C differs from the combination of Metal 1 and Metal 2 for PMOS gate 330C. In other words, the Metal 1 and Metal 2 for NMOS gate 310C are not necessarily the same as the Metal 1 and Metal 2 for PMOS gate 330C.

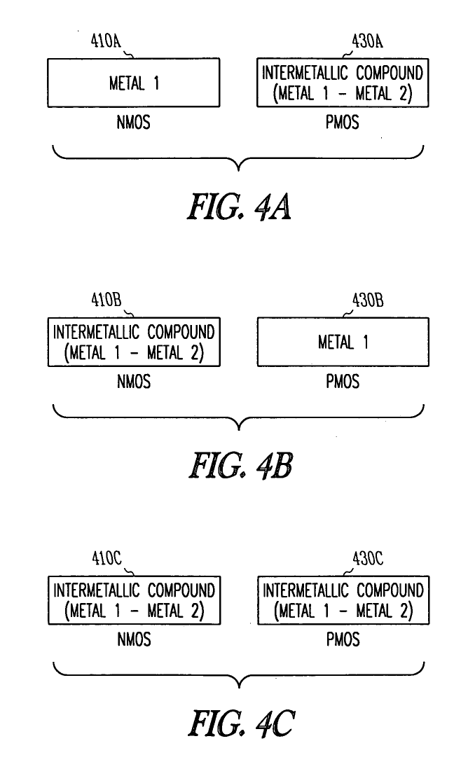

FIGS. 4A-4C are each an illustration of an embodiment of gates of the NMOS transistor and the PMOS transistor after the annealing. After the metal layers are formed as illustrated in FIGS. 3A-3C, a high temperature anneal is performed, resulting in the metal gates illustrated in FIGS. 4A-4C. The time and temperature of the annealing step depend both upon the diffusion rates of the metals being used and the metal thickness. The maximum temperature is the lower of the maximum temperature of stability of the compound or the maximum temperature that the device structure can tolerate. In one embodiment, in which Metal 1 is titanium and Metal 2 is platinum, the annealing temperature is up to 825° C. In another embodiment, in which Metal 1 is titanium and Metal 2 is palladium, the annealing temperature is about 500° C. In another embodiment, in which Metal 1 is tantalum and Metal 2 is iridium, the annealing temperature is about the maximum temperature tolerable by the CMOS device being manufactured.

FIG. 4A illustrates an NMOS gate 410A and a PMOS gate 430A. NMOS gate 410A illustrates a specific embodiment of gate 210 of NMOS transistor 201. PMOS gate 430A illustrates a specific embodiment of gate 230 of PMOS transistor 221. NMOS gate 410A includes a layer of Metal 1. PMOS gate 430A includes a layer of the intermetallic compound of Metal 1 and Metal 2.

FIG. 4B illustrates an NMOS gate 410B and a PMOS gate 430B. NMOS gate 410B illustrates another specific embodiment of gate 210 of NMOS transistor 201. PMOS gate 430B illustrates another specific embodiment of gate 230 of PMOS transistor 221. NMOS gate 410B includes a layer of the intermetallic compound of Metal 1 and Metal 2. PMOS gate 430B includes a layer of Metal 1.

FIG. 4C illustrates an NMOS gate 410C and a PMOS gate 430C. NMOS gate 410C illustrates another specific embodiment of gate 210 of NMOS transistor 201. PMOS gate 430C illustrates another specific embodiment of gate 230 of PMOS transistor 221. NMOS gate 410C includes a layer of the intermetallic compound of Metal 1 and Metal 2. PMOS gate 430C includes a layer of the intermetallic compound of Metal 1 and Metal 2. In another specific embodiment, two different intermetallic compounds are used for NMOS gate 410C and PMOS gate 430C. While it is possible to use intermetallic compounds composed of entirely different metals, for simplicity in processing, it is desirable, if possible, to have as few depositions as possible. Therefore, having at least one metal in common on each type of gate is generally desired.

The CMOS transistor gates and the processes are discussed with reference to FIGS. 3A-3C and 4A-4C as examples for illustrative purpose only. For example, Metal 1 and Metal 2 may be deposited in a different order. In general, deposition of one or more metals and the subsequent annealing, which results in intermetallic compounds when more than one metal is deposited to form a gate, allows adjustment of the work function to optimize the threshold voltage of CMOS transistors. Specific embodiments are discussed below for several metals. In various embodiments, during fabrication of a CMOS device, at least one of the gate metals is deposited using ALD.

Platinum and titanium have work functions about 1 eV apart. On a silicon oxide gate insulator and silicon substrate, the work function of platinum is about 5.3 eV, and the work function of titanium is about 4.3 eV. In one embodiment, a layer of titanium is deposited in both NMOS and PMOS gate areas, and a layer of platinum is added onto the layer of titanium in PMOS gate areas. An intermetallic compound of platinum and titanium is formed by annealing subsequent to the deposition of the layer of platinum. The composition is selected to adjust the work function to a value lower than that of platinum for optimization of the threshold voltage for the PMOS transistor. There are three possible intermetallic compounds of platinum and titanium: Pt₃Ti, PtTi, and PtTi₃. Pt₃Ti has a work function closer to that of platinum (5.3 eV) than that of titanium (4.3 eV), and lower than that of platinum. A lower work function lowers the PMOS threshold voltage (to a negative value of larger magnitude), requiring a larger magnitude negative gate voltage to turn the transistor on and enhance conduction.

In another embodiment, a layer of titanium is deposited on the NMOS gate areas, and a layer of platinum is added onto the layer of titanium. By annealing, the intermetallic compound PtTi₃ is formed, with a work function of around 4.6 eV, slightly higher than that of titanium alone (4.3 eV). An NMOS transistor gate metal with a higher work function increases the NMOS threshold voltage (to a positive value of larger magnitude), requiring a larger magnitude positive gate voltage to turn the transistor on and enhance conduction. In order to insure proper operation, it is desirable that the metal in contact with the silicon be a single-phase material that is either thermodynamically stable or meta-stable over the life of the product.

Platinum thin films have been grown at 300° C. by ALD using (methylcyclopentadienyl)trimethylplatinum (MeCpPtMe₃) and oxygen as precursors (Aaltonen et al., Chemistry of Materials, 15(9):1924-28 (2003)). The films had excellent uniformity, low resistivity, and low impurity contents. Growth rates of 0.45 Å cycle (−1) were obtained with 4-second total cycle times.

Palladium has a high work function of 5.1 eV and can be alloyed with titanium to form the intermetallic compound PdTi. In one embodiment, a layer of titanium is deposited on the NMOS gate areas, and a layer of palladium is added onto the layer of titanium. By annealing, the intermetallic compound PdTi is formed, with a work function of about 4.7 eV, which is between the work function of palladium (5.1 eV) and the work function of Ti alone (4.3 eV). An NMOS transistor gate metal with a higher work function increases the NMOS threshold voltage (to a positive value of larger magnitude), requiring a larger magnitude positive gate voltage to turn the transistor on and enhance conduction.

Ruthenium, palladium, and platinum complexes of 2,2,6,6-tetramethyl-3,5-heptanedione (thd) and ruthenium tris acetylacetonate (asas) were synthesized and studied with TG, DTA, DSC and MS methods (Lashdaf et al., J. Thermal Analysis and Calorimetry, 64(3):1171-82 (2001)). The platinum thd complex has the highest volatility despite the second highest molecular mass of the complex. All the complexes sublimed under reduced pressure.

Iridium has a high work function of 5.1 eV and can be alloyed with tantalum to form the intermetallic compound IrTa. In one embodiment, a layer of titanium is deposited on NMOS gate areas, and a layer of iridium is added onto the layer of titanium. By annealing, the intermetallic compound IrTa is formed, with a work function of about 4.7 eV, between the work function of iridium (5.1 eV) and the work function of tantalum (4.3 eV). An NMOS transistor gate metal with a higher work function increases the NMOS threshold voltage (to a positive value of larger magnitude), requiring a larger magnitude positive gate voltage to turn the transistor on and enhance conduction.

An example of using iridium for transistor gates with high-K gate dielectrics is discussed in U.S. patent application Ser. No. 11/152,759, entitled “IRIDIUM/ZIRCONIUM OXIDE STRUCTURE,” filed on Jun. 14, 2005, assigned to Micron Technology, Inc., which is incorporated herein by reference in its entirety. Iridium thin films were deposited by ALD using Ir(acac)₃ (Aaltonen et al., J. Electrochem. Soc. 151 (8):G489-92 (2004)). Key parameters include Ir(acac)₃ evaporation temperature of 150° C., air flow rate of 5-40 sccm, Ir(acac)₃ pulse time of 0.2-2.5 seconds, air pulse time of 0.5-2.5 seconds, purge time of 0.5 seconds, deposition temperature of 200-400° C., N₂ flow rate of 400 sccm, and reactor pressure of 10 mbar.

A process for producing intermetallic aluminum based compounds for use as contact layers in LSI circuits is discussed in U.S. Pat. No. 3,830,657, entitled “Method for making integrated circuit contact structure,” which is incorporated herein by reference in its entirety. The process uses evaporation of a thin layer of aluminum followed by a thin layer of the compound forming material (preferably copper), followed by the evaporation of the balance of the conducting layer. In this case the objective was to prevent the silicon in the device layer from diffusing into the metallurgy, thus causing the formation of metal ‘spikes’. The compound formed is Al₂Cu. As aluminum has a low solubility of copper, at modest temperatures, the resulting structure was essentially thermodynamically stable, at the temperatures of manufacture and use (room temperature to 400° C.).

In the case of Al₂Cu, the solubility of copper in aluminum at low to moderate temperatures is a fraction of one percent, and the compound is stable once formed. A different process is used in the case of the platinum and palladium compounds such as Pt₃Ti, PtTi, PtTi₃, or PdTi. In the case of platinum and palladium, over 10% of titanium is soluble in each of the elements. Over 10% tantalum is soluble in iridium. About 5% Iridium is soluble in Ta. Thus the process is modified. A layer of titanium of a few hundred angstroms thick is deposited on the gate insolator during fabrication of the device and the opening of the gate areas. A layer of platinum or palladium is then deposited, such as by ALD, upon the layer of titanium, with the thickness of the layer of platinum or palladium being just sufficient to produce the desired composition. The composition may be the stoichiometric composition of one of the compounds or an off-stoichiometric composition depending upon the work function desired, provided that the resulting composition is within the solubility range of the compound. The metal layers are then annealed to form the desired compound. To form the intermetallic compound of platinum and titanium, the annealing is performed with a temperature at or below 825° C. To form the intermetallic compound of palladium and titanium, the annealing is performed with a temperature at about 500° C. To form the intermetallic compound of iridium and tantalum, the annealing is performed at a much higher temperature, with the limit of temperature being determined by the tolerance of the device structures.

In one embodiment, two different intermetallic compounds are used to more closely match the ideal threshold voltage of the devices. In this embodiment, an additional mask level is necessary to allow for the adjustment of the composition on the second set of devices. In one embodiment, a layer of Pd—Ti compound placed in contact with the gates of a PMOS device and an aluminum metallurgy with a Al₂Cu layer placed in contact with the NMOS device is used as both an NMOS contact and the first level interconnect.

In one embodiment, upon the completion of the annealing, a conducting layer is deposited. In one embodiment, the conductor layer includes one of the constituents of the intermetallic compound. In another embodiment, the conductor layer is formed with a metal that is not one of the constituents of the intermetallic compound. When the conducting layer is formed with copper, for example, care is taken such that the intermetallic barrier is sufficiently thick and the coverage is complete enough to prevent the diffusion of copper into the junctions either during manufacturing or during use.

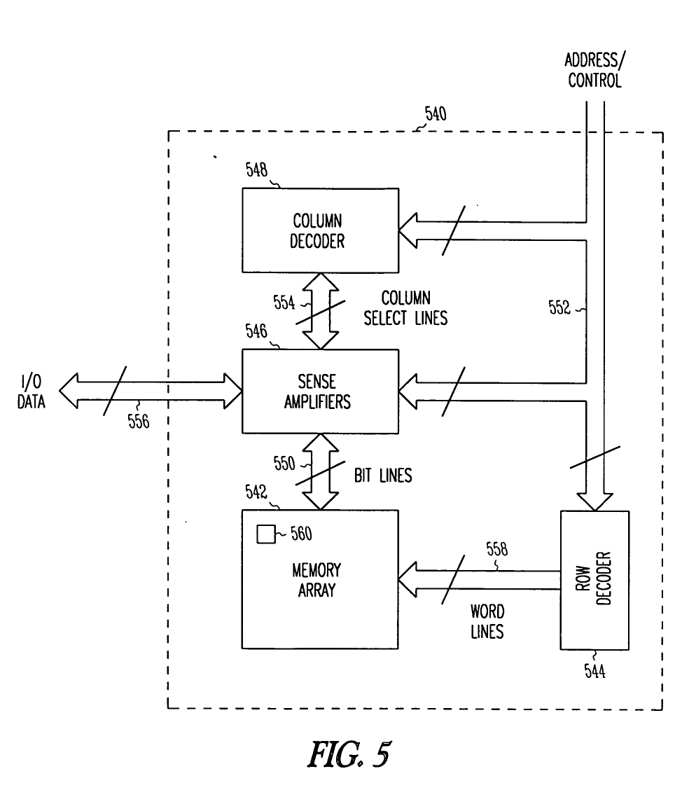

FIG. 5 is a block diagram illustrating an embodiment of a memory device 540 utilizing the CMOS device of FIG. 2. Memory device 540 contains a memory array 542, a row decoder 544, a column decoder 548, and sense amplifiers 546. Memory array 542 includes a plurality of transistor cells 560 that have gates formed with a metal or an intermetallic compound as discussed above. Word lines 558 and bit lines 550 are commonly arranged into rows and columns. Bit lines 550 of memory array 542 are connected to sense amplifiers 546, while word lines 558 are connected to row decoder 544. Address and control signals are input on address/control lines 552 into memory device 540 and connected to column decoder 548, sense amplifiers 546 and row decoder 544 and are used to gain read and write access, among other things, to memory array 542.

Column decoder 548 is connected to sense amplifiers 546 via control and column select signals on column select lines 554. Sense amplifiers 546 receives input data destined for memory array 542 and outputs data read from memory array 542 over input/output (I/O) data lines 556. Data is read from the cells of memory array 542 by activating one of word lines 558 (via the row decoder 544), which couples all of the memory cells corresponding to that word line to respective bit lines 550, which define the columns of the array. One or more bit lines 550 are also activated. When a particular word line 558 and bit lines 550 are activated, sense amplifiers 546 connected to a bit line column detects and amplifies the conduction sensed through a given transistor cell and transferred to its bit line 550 by measuring the potential difference between the activated bit line 550 and a reference line which may be an inactive bit line. In the read operation the source region of a given cell is couple to a bit line. The operation of Memory device sense amplifiers is described, for example, in U.S. Pat. Nos. 5,627,785; 5,280,205; and 5,042,011, all assigned to Micron Technology Inc., which are incorporated by reference herein in their entirety.

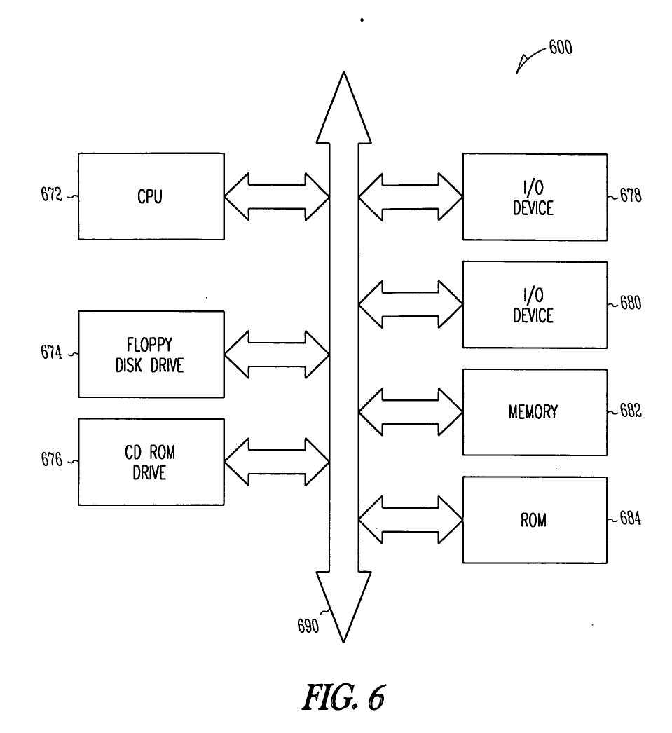

FIG. 6 is a block diagram illustrating an embodiment of a processor-based system utilizing the CMOS device of FIG. 2. FIG. 6 is a block diagram of an electrical system, or processor-based system, 600 utilizing transistor cells having gates formed with a metal or an intermetallic compound as discussed above. For example, by way of example and not by way of limitation, memory 682 is constructed in accordance with the present invention to have transistor cells having ternary metallic gates formed by atomic layer deposition. However, the present subject matter is not so limited and the same can apply to transistors in the CPU, etc. The processor-based system 600 may be a computer system, a process control system or any other system employing a processor and associated memory. System 600 includes a central processing unit (CPU) 672, e.g., a microprocessor that communicates with the memory 682 and an I/O device 678 over a bus 690. It is noted that bus 690 may be a series of buses and bridges commonly used in a processor-based system, but for convenience purposes only, bus 690 has been illustrated as a single bus. A second I/O device 680 is illustrated, but is not necessary to practice the invention. The processor-based system 600 can also includes read-only memory (ROM) 684 and may include peripheral devices such as a floppy disk drive 674 and a compact disk (CD) ROM drive 676 that also communicates with the CPU 672 over the bus 690 as is well known in the art.

It will be appreciated by those skilled in the art that additional circuitry and control signals can be provided, and that the processor-based system 600 has been simplified to help focus on the invention.

It is to be understood that FIG. 6 illustrates an embodiment for electronic system circuitry in which one or more CMOS devices each including transistor gates formed with one or more intermetallic compounds, are used. The illustration of system 600, as shown in FIG. 6, is intended to provide a general understanding of one application for the structure and circuitry of the present invention, and is not intended to serve as a complete description of all the elements and features of an electronic system using the novel ternary metallic gate transistor cells formed by atomic layer deposition. Further, the invention is equally applicable to any size and type of system 600 using the one or more CMOS devices each including transistor gates formed with one or more intermetallic compounds, and is not intended to be limited to that described above. As one of ordinary skill in the art will understand, such an electronic system can be fabricated in single-package processing units, or even on a single semiconductor chip, in order to reduce the communication time between the processor and the memory device.

Applications containing the one or more CMOS devices each including transistor gates formed with one or more intermetallic compounds, as described in this disclosure, include electronic systems for use in memory modules, device drivers, power modules, communication modems, processor modules, and application-specific modules, and may include multilayer, multichip modules. Such circuitry can further be a subcomponent of a variety of electronic systems, such as a clock, a television, a cell phone, a personal computer, an automobile, an industrial control system, an aircraft, and others.

This disclosure includes several processes and structures. The present invention is not limited to a particular process order or structural arrangement. Although specific embodiments have been illustrated and described herein, it will be appreciated by those of ordinary skill in the art that any arrangement which is calculated to achieve the same purpose may be substituted for the specific embodiments shown. This application is intended to cover adaptations or variations. It is to be understood that the above description is intended to be illustrative, and not restrictive. Combinations of the above embodiments, and other embodiments, will be apparent to those of skill in the art upon reviewing the above description. The scope of the present invention should be determined with reference to the appended claims, along with the full scope of equivalents to which such claims are entitled.

What is claimed is:

1. A CMOS device, comprising:
NMOS transistors each including an NMOS gate; and
PMOS transistors each including a PMOS gate,
wherein at least one of the NMOS gate and the PMOS gate includes a layer of intermetallic compound of a first metal and a second metal, the layer of intermetallic compound formed by depositing a layer of the first metal, depositing a layer of the second metal on the layer of the first metal, and annealing.

2. The CMOS device of claim 1, wherein the first metal is titanium (Ti).

3. The CMOS device of claim 2, wherein the second metal is palladium (Pd).

4. The CMOS device of claim 1, wherein the first metal is titanium (Ti).

5. The CMOS device of claim 4, wherein the second metal is platinum (Pt).

6. The CMOS device of claim 1, wherein the first metal is iridium (Ir).

7. The CMOS device of claim 6, wherein the second metal is tantalum (Ta).

8. The CMOS device of claim 1, wherein at least one of the layer of the first metal and the layer of the second metal is deposited by atomic layer deposition.

9. A CMOS device, comprising:
first type MOS transistors each including:
a gate including a layer of intermetallic compound of a first metal and a second metal; and
a conducting layer in contact with the layer of intermetallic compound.

10. The CMOS device of claim 9, wherein the conducting layer comprises one of the first metal and the second metal.

11. The CMOS device of claim 10, wherein the first metal is titanium (Ti), and the second metal is palladium (Pd).

12. The CMOS device of claim 10, wherein the first metal is titanium (Ti), and the second metal is platinum (Pt).

13. The CMOS device of claim 10, wherein the first metal is iridium (Ir), and the second metal is tantalum (Ta).

14. The CMOS device of claim 9, wherein the conducting layer comprises a third metal different from the first metal and different from the second metal.

15. The CMOS device of claim 14, wherein the third metal is one of aluminum (Al) and an aluminum alloy.

16. The CMOS device of claim 14, wherein the third metal is one of copper (Cu) and a copper alloy.

17. The CMOS device of claim 14, wherein the third metal is one of silver (Ag) and a sliver alloy.

18. The CMOS device of claim 14, wherein the third metal is one of gold (Au) and a gold alloy.

19. The CMOS device of claim 9, wherein the first type MOS transistors comprise NMOS transistors.

20. The CMOS device of claim 9, wherein the first type MOS transistors comprise PMOS transistors.

21. A method for producing a CMOS device, the method comprising:
forming an NMOS gate for an NMOS transistor; and
forming a PMOS gate for a PMOS transistor,
wherein at least one of forming the NMOS gate and forming the PMOS gate includes:
forming a first metal layer by depositing the first metal;
forming a second metal layer on the first metal layer by depositing the second metal; and
forming a layer of intermetallic compound by annealing.

22. The method of claim 21, further comprising controlling a threshold voltage of at least one of the NMOS transistor and the PMOS transistor by selecting the first metal and the second metal.

23. The method of claim 21, wherein forming the first metal layer comprises forming the first metal layer by atomic layer deposition of the first metal.

24. The method of claim 21, wherein forming the second metal layer comprises forming the second metal layer by atomic layer deposition of the second metal.

25. The method of claim 21, wherein forming the first metal layer comprises forming a layer of titanium (Ti).

26. The method of claim 25, wherein forming the second metal layer comprises forming a layer of palladium (Pd).

27. The method of claim 21, wherein forming the first metal layer comprises forming a layer of titanium (Ti).

28. The method of claim 27, wherein forming the second metal layer comprises forming a layer of platinum (Pt).

29. The method of claim 21, wherein forming the first metal layer comprises forming a layer of iridium (Ir).

30. The method of claim 29, wherein forming the second metal layer comprises forming a layer of tantalum (Ta).

31. A method for producing a CMOS device, the method comprising:
selecting a first metal and a second metal for a specified threshold voltage of first type transistors, the first metal and the second metal capable of forming an intermetallic compound;
depositing a layer of the first metal to form a gate for each of the first type transistors;
depositing a layer of the second metal on the layer of the first metal for the each of the first type transistors; and
performing annealing to form a layer of the intermetallic compound with the layer of the first metal and the layer of the second metal.

32. The method of claim 31, wherein at least one of depositing the layer of the first metal and depositing the layer of the first metal comprises using atomic layer deposition.

33. The method of claim 32, wherein depositing the layer of the first metal comprises depositing titanium (Ti), and depositing the layer of the second metal comprises depositing palladium (Pd).

34. The method of claim 32, wherein depositing the layer of the first metal comprises depositing titanium (Ti), and depositing the layer of the second metal comprises depositing platinum (Pt).

35. The method of claim 32, wherein depositing the layer of the first metal comprises depositing tantalum (Ta), and depositing the layer of the second metal comprises depositing iridium (Ir).

36. The method of claim 32, further comprising depositing a conducting layer on the layer of intermetallic compound subsequent to the performing the annealing to form the layer of the intermetallic compound.

37. The method of claim 35, wherein depositing the conducting layer comprises depositing a layer of one of the first metal and the second metal.

38. The method of claim 35, wherein depositing the conducting layer comprises depositing a layer of a third metal different from the first metal and different from the second metal.

39. The method of claim 38, wherein depositing the conducting layer comprises depositing a layer of one of aluminum (Al), copper (Cu), silver (Ag), gold (Au), and an alloy containing one of aluminum (Al), copper (Cu), silver (Ag), gold (Au).
